(19) United States
(12) Patent Application Publication
(10) Pub. No.: US 2023/0387597 A1
(43) Pub. Date: Nov. 30, 2023

(54) ANTENNA STRUCTURE AND IMAGE DISPLAY DEVICE INCLUDING THE SAME

(71) Applicant: DONGWOO FINE-CHEM CO., LTD., Jeollabuk-do (KR)

(72) Inventor: Won Hee LEE, Gyeonggi-do (KR)

(21) Appl. No.: 18/200,734

(22) Filed: May 23, 2023

(30) Foreign Application Priority Data
May 24, 2022 (KR) 10-2022-0063641

(51) Int. Cl. H01Q 9/04; H01Q 1/24; H03H 1/00

(52) U.S. Cl. CPC H01Q 9/045; H01Q 1/243; H03H 1/00

(57) ABSTRACT

An antenna structure according to an embodiment includes a first radiator, a second radiator arranged along a first direction together with the first radiator, and a third radiator arranged along a second direction together with the second radiator. The second direction is perpendicular to the first direction. At least one of the first radiator, the second radiator and the third radiator comprises an impedance matching pattern having a solid structure.

### CROSS-REFERENCE TO RELATED APPLICATION AND CLAIM OF PRIORITY

This application claims the benefit under 35 USC § 119 of Korean Patent Application No. 10-2022-0063641 filed on May 24, 2022, in the Korean Intellectual Property Office (KIPO), the entire disclosures of which is incorporated herein by reference for all purposes.

### BACKGROUND

### 1. Field

The present invention relates to an antenna structure and an image display device including the same. More particularly, the present invention relates to an antenna structure including a plurality of radiators and an image display device including the same.

### 2. Description of the Related Art

As information technologies have been developed, a wireless communication technology such as Wi-Fi, Bluetooth, etc., or a non-contact sensing such as a gesture detection and a motion recognition is being applied to or embedded in image display devices, electronic devices and architecture.

Further, an antenna for performing communication in a high frequency or ultra-high frequency band is applied to various mobile devices according to an evolution of a mobile communication technology.

For example, the wireless communication technology is combined with a display device in, e.g., a smartphone form. In this case, the antenna may be combined with the display device to provide a communication function.

As the display device to which the antenna is employed becomes thinner and lighter, a space for the antenna may also decrease. Accordingly, the antenna may be included in the form of a film or patch on a display panel so as to insert the antenna in a limited space.

However, when the antenna is disposed on the display panel, a coaxial circuit for transmitting and receiving signals or performing a feeding may not be easily constructed. Further, sensitivity may be lowered, or spatial efficiency and aesthetic property of a structure to which an antenna device is applied may be hindered due to an insertion of a coaxial power supply circuit.

For example, Korean Patent Publication No. 10-2014-0104968 discloses an antenna device including an antenna element and a ground element.

### SUMMARY

According to an aspect of the present invention, there is provided an antenna structure having improved signaling efficiency and radiation reliability.

According to an aspect of the present invention, there is provided a display device including the antenna structure.
(1) An antenna structure, including: a first radiator; a second radiator arranged along a first direction together with the first radiator; and a third radiator arranged along a second direction perpendicular to the first direction together with the second radiator, wherein at least one of the first radiator, the second radiator and the third radiator includes an impedance matching pattern having a solid structure.
(2) The antenna structure according to the above (1), further including: a first transmission line connected to the first radiator at the same layer as that of the first radiator; a second transmission line connected to the second radiator at the same layer as that of the second radiator; and a third transmission line connected to the third radiator at the same layer as that of the third radiator.
(3) The antenna structure according to the above (2), wherein at least one of the first transmission line, the second transmission line and the third transmission line has a solid structure.
(4) The antenna structure according to the above (2), further including a dielectric layer on which the first radiator, the second radiator and the third radiator are disposed, wherein the first direction is inclined by a first tilting angle with respect to a width direction of the dielectric layer, and the second direction is inclined by a second tilting angle with respect to the width direction of the dielectric layer.
(5) The antenna structure according to the above (4), wherein each of the first tilting angle and the second tilting angle is in a range from 30° to 60°.
(6) The antenna structure according to the above (4), wherein the impedance matching pattern includes a first impedance matching pattern included in the first radiator and directly connected to the first transmission line, and a third impedance matching pattern included in the third radiator and directly connected to the third transmission line.
(7) The antenna structure according to the above (4), wherein the impedance matching pattern includes a second impedance matching pattern included in the second radiator and directly connected to the second transmission line.
(8) The antenna structure according to the above (2), further including a dielectric layer on which the first radiator, the second radiator, and the third radiator are disposed, wherein the first direction is parallel to a width direction of the dielectric layer, the second direction is perpendicular to the width direction of the dielectric layer.
(9) The antenna structure according to the above (8), wherein the impedance matching pattern includes a first impedance matching pattern included in the first radiator, a second impedance matching pattern included in the second radiator, and a third impedance matching pattern included in the third radiator, and the first impedance matching pattern and the second impedance matching pattern are directly connected to the first transmission line and the second transmission line, respectively.
(10) The antenna structure according to the above (9), wherein the third impedance matching pattern is physically spaced apart from the third transmission line.
(11) The antenna structure according to the above (9), wherein the second impedance matching pattern surrounds two sides among four sides of the second radiator.
(12) The antenna structure according to the above (1), wherein the first radiator, the second radiator and the third radiator are disposed at the same layer.
(13) The antenna structure according to the above (1), further including: a fourth radiator spaced apart from the first radiator, the second radiator and the third radiator; and a fourth transmission line connected to the fourth radiator at the same layer as that of the fourth radiator, wherein the impedance matching pattern includes a fourth impedance matching pattern included in the fourth radiator and directly connected to the fourth transmission line.
(14) The antenna structure according to the above (13), wherein the first radiator, the second radiator and the third radiator serve as a receiving radiation unit, and the fourth radiator serves as a transmitting radiation unit.
(15) A motion recognition sensor including the antenna structure according to the above-described embodiments.
(16) An image display device, including: a display panel; and the antenna structure according to the above-described embodiments.
(17) The image display device according to the above (16), wherein the first direction is inclined by a first tilting angle with respect to a length direction or a width direction of the display panel, and the second direction is inclined by a second tilting angle with respect to the length direction or the width direction of the display panel.
(18) The image display device according to the above (16), further including: a motion sensor driving circuit coupled to the antenna structure; and a flexible circuit board (FPCB) electrically connecting the antenna structure and the motion sensor driving circuit.

According to embodiments of the present invention, an antenna structure may include a first radiator, a second radiator, a third radiator and a fourth radiator which may be driven independently from each other. A first direction in which the first radiator and the second radiator are arranged and a second direction in which the third radiator and the second radiator are arranged may be perpendicular to each other. Thus, a strength and a change of a signal from the radiators in two orthogonal directions may be detected by the antenna structure.

In example embodiments, at least one of the radiators may include an impedance matching pattern having a solid structure. Accordingly, driving properties of the antenna structure may be improved, and an impedance matching may be improved.

In some embodiments, the first direction and the second direction may be inclined at a predetermined tilting angle with respect to one side of the dielectric layer or one side of a display panel. Accordingly, signal imbalance of radiators in a first axis and a second axis may be resolved, and motion or gesture sensing performance may be improved by the antenna structure.

The antenna structure may be electrically coupled to a motion sensor driving circuit through a circuit board. Thus, changes of signal strength in the first axis and the second axis according to a position change of an object to be sensed may be transmitted to the motion sensor driving circuit, and the position change and distance in all directions can be measured based on collected information.

### BRIEF DESCRIPTION OF THE DRAWINGS

FIGS. 1 and 2 are schematic plan views illustrating antenna structures in accordance with exemplary embodiments.

FIG. 3 is a schematic plan view illustrating an antenna structure in accordance with exemplary embodiments.

FIG. 4 is a schematic plan view illustrating an antenna structure in accordance with exemplary embodiments.

FIGS. 5 and 6 are a schematic plan view and a cross-sectional view illustrating a display device in accordance with exemplary embodiments.

### DETAILED DESCRIPTION OF THE EMBODIMENTS

According to exemplary embodiments of the present invention, an antenna structure including a plurality of radiators arranged in two orthogonal directions. According to exemplary embodiments of the present invention, an image display device including the antenna structure is also provided.

However, an application of the antenna structure is not limited to the display device, and the antenna structure may be applied to various objects or structures such as a vehicle, a home electronic appliance, an architecture, etc.

Hereinafter, the present invention will be described in detail with reference to the accompanying drawings. However, those skilled in the art will appreciate that such embodiments described with reference to the accompanying drawings are provided to further understand the spirit of the present invention and do not limit subject matters to be protected as disclosed in the detailed description and appended claims.

The terms “first”, “second”, “third”, “fourth”, “one end”, “other end”, “upper side”, “lower side”, “upper side”, “lower side”, etc., as used herein are not intended to limit an absolute position or order, but is used in a relative sense to distinguish different components or elements.

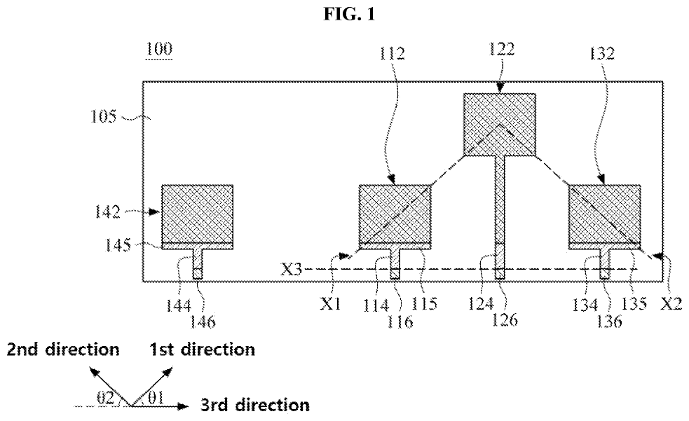

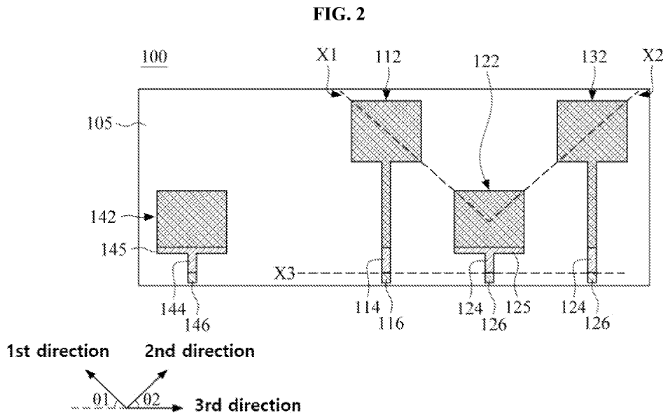

FIGS. 1 and 2 are schematic plan views illustrating antenna structures in accordance with exemplary embodiments.

Referring to FIG. 1, the antenna structure may include a dielectric layer 105, and a first radiator 112, a second radiator 122 and a third radiator 132 disposed on the dielectric layer 105.

The dielectric layer 105 may include, e.g., a transparent resin material. For example, the dielectric layer 105 may include a polyester-based resin such as polyethylene terephthalate, polyethylene isophthalate, polyethylene naphthalate and polybutylene terephthalate; a cellulose-based resin such as diacetyl cellulose and triacetyl cellulose; a polycarbonate-based resin; an acrylic resin such as polymethyl (meth)acrylate and polyethyl (meth)acrylate; a styrene-based resin such as polystyrene and an acrylonitrile-styrene copolymer; a polyolefin-based resin such as polyethylene, polypropylene, a cycloolefin or polyolefin having a norbornene structure and an ethylene-propylene copolymer; a vinyl chloride-based resin; an amide-based resin such as nylon and an aromatic polyamide; an imide-based resin; a polyethersulfone-based resin; a sulfone-based resin; a polyether ether ketone-based resin; a polyphenylene sulfide resin; a vinyl alcohol-based resin; a vinylidene chloride-based resin; a vinyl butyral-based resin; an allylate-based resin; a polyoxymethylene-based resin; an epoxy-based resin; a urethane or acrylic urethane-based resin; a silicone-based resin, etc. These may be used alone or in a combination of two or more thereof.

The dielectric layer 105 may include an adhesive material such as an optically clear adhesive (OCA), an optically clear resin (OCR), or the like. In some embodiments, the dielectric layer 105 may include an inorganic insulating material such as glass, silicon oxide, silicon nitride, silicon oxynitride, etc.

In an embodiment, the dielectric layer 105 may be provided as a substantially single layer.

In an embodiment, the dielectric layer 105 may include a multi-layered structure of at least two layers. For example, the dielectric layer 105 may include a substrate layer and an antenna dielectric layer, and may include an adhesive layer between the substrate layer and the antenna dielectric layer.

Capacitance or inductance for the antenna structure 100 may be formed by the dielectric layer 105, so that a frequency band at which the antenna structure may be driven or operated may be adjusted. In some embodiments, a dielectric constant of the dielectric layer 105 may be adjusted in a range from about 1.5 to about 12. If the dielectric constant exceeds about 12, a driving frequency may be excessively decreased, and driving in a desired high frequency or ultrahigh frequency band may not be implemented.

In some embodiments, a ground layer (not illustrated) may be disposed on a bottom surface of the dielectric layer 105. Generation of an electric field in a transmission line may be more promoted by the ground layer, and an electrical noise around the transmission line may be absorbed or shielded.

In some embodiments, the ground layer may be included an individual member of the antenna structure 100. In some embodiments, a conductive member of a display device to which the antenna structure 100 is applied may serve as the ground layer.

For example, the conductive member may include various electrodes or wirings such as, e.g., a gate electrode, a source/drain electrode, a pixel electrode, a common electrode, a scan line, a data line, etc., included in a thin film transistor (TFT) array of a display panel.

In an embodiment, a metallic member disposed at a rear portion of the display device such as a SUS plate, a sensor member such as a digitizer, a heat dissipation sheet, etc., may serve as the ground layer.

In example embodiments, the first radiator 112 and the second radiator 122 may be arranged in a first direction. For example, the first radiator 112 and the second radiator 122 may be spaced apart from each other along a first axis X1 extending in the first direction. The first axis X1 may be an imaginary straight line passing through central points of the first radiator 112 and the second radiator 122 and extending in the first direction.

In example embodiments, the second radiator 122 and the third radiator 132 may be arranged in a second direction perpendicular to the first direction. For example, the second radiator 122 and the third radiator 132 may be spaced apart from each other along a second axis X2 extending in the second direction. The second axis X2 may be an imaginary straight line passing through central points of the second radiator 122 and the third radiator 132 and extending in the second direction.

For example, the first radiator 112, the second radiator 122 and the third radiator 132 may be spaced apart from each other to implement independent radiation properties and signal reception functions. Additionally, a change of a signal intensity in the first direction and the second direction according to a position change of a sensing object in the first direction and/or the second direction may be measured. A motion and moving distance of the sensing object may be detected through the change of the measures signal intensity.

In example embodiments, the first direction and the second direction may be perpendicular to each other. Accordingly, the antenna structure 100 may transmit the change of the signal intensity in directions of two orthogonal axes X1 and X2 to a motion sensor. The motion sensor may measure a position change and distance in all directions on an X-Y coordinate system based on the collected information.

For example, the antenna structure 100 may be provided as a motion sensor that detects motion in two axes perpendicular to each other, and the first to third radiators 112, 122, and 132 may be provided as receiving radiation units for detecting motion.

For example, the second radiator 122 may serve as a reference point for measuring the change of the signal intensity along the first axis X1 and the second axis X2. For example, a positional change of the sensing object may be detected by measuring the change of the signal intensity along the first axis X1 and the second axis X2 based on a signal intensity from the second radiator 122.

In some embodiments, each of the first to third radiators 112, 122, and 132 may be designed to have a resonance frequency in a high or ultra-high frequency band of 3G, 4G, 5G or higher. For example, the resonance frequency of each of the first to third radiators 112, 122 and 132 may be about 50 GHz or more, from 50 GHz to 75 GHz, or from 55 GHz to 65 GHz.

In some embodiments, a spacing distance of the first radiator 112 and the second radiator 122 in the first direction and a spacing distance of the second radiator 122 and the third radiator 132 in the second direction may be substantially the same. Accordingly, the signal intensity in the first direction and/or the second direction may be measured at a regular distance interval. Therefore, the change of the signal intensity in the first direction and/or the second direction according to the positional change of the sensing object may be more accurately measured.

In example embodiments, at least one of the first radiator 112, the second radiator 122 and the third radiator 132 may include an impedance matching pattern 115, 125 and 135 having a solid structure. Thus, an impedance matching of signals transmitted to the antenna structure 100 may be improved and an antenna gain may be increased.

The impedance matching patterns 115, 125 and 135 may be formed to surround at least one side among four sides of at least one of the first to third radiators 112, 122 and 132. For example, the impedance matching pattern may be formed on a lower side or one side of at least one of the first to third radiators 112, 122 and 132.

For example, regions of the first to third radiators 112, 122 and 132 except for the impedance matching pattern may include a mesh pattern structure. Accordingly, a visual recognition of the antenna structure 100 from an outside may be prevented.

For example, the impedance matching patterns 115, 125 and 135 may be disposed in a non-display area of an image display device. Accordingly, a resistance may be lowered reduced while preventing the antenna structure 100 from being visible to a user, so that signal transfer efficiency and antenna driving properties may be improved.

In some embodiments, the antenna structure 100 may further include a first transmission line 114, a second transmission line 124 and a third transmission line 134 connected to the first radiator 112, the second radiator 122 and the third radiator 132, respectively. Thus, the first radiator 112, the second radiator 122 and the third radiator 132 may be driven independently from each other. Further, the change of the signal intensity of electromagnetic wave in the directions of the first axis X1 and the second axis X2 may be independently measured.

The first transmission line 114 may be electrically connected to the first radiator 112 at the same layer as that of the first radiator 112. For example, the first transmission line 114 may be integral with the first radiator 112 and may extend from one end of the first radiator 112.

The second transmission line 124 may be electrically connected to the second radiator 122 at the same layer as that of the second radiator 122. For example, the second transmission line 124 may be integral with the second radiator 122 and may extend from one end of the second radiator 122.

The third transmission line 134 may be electrically connected to the third radiator 132 at the same layer as that of the third radiator 132. For example, the third transmission line 134 may be integral with the third radiator 132 and may extend from one end of the third radiator 132.

For example, the first transmission line 114, the second transmission line 124, and the third transmission line 134 may transmit a driving signal or a power from an antenna driving integrated circuit (IC) chip to the first radiator 112, the second radiator 122 and the third radiator 132, respectively.

For example, the first transmission line 114, the second transmission line 124, and the third transmission line 134 may transmit an electromagnetic wave signal or an electrical signal from the first radiator 112, the second radiator 122 and the third radiator 132, respectively, to the antenna driving IC chip or a motion sensor driving circuit.

In some embodiments, the first transmission line 114, the second transmission line 124 and the third transmission line 134 may be disposed at the same layer or at the same level together with the first radiator 112, the second radiator 122 and the third radiator 132 on the dielectric layer 105.

The transmission lines 114, 124 and 134 may be disposed at the same level as that of the radiators 112, 122 and 132, so that feeding/driving may be implemented without an additional separate coaxial feeding for signal input/output and power supply. Thus, for example, an antenna on display (AoD) in which the antenna structure 100 is disposed on a display panel may be implemented.

In some embodiments, at least one of the first transmission line 114, the second transmission line 124 and the third transmission line 134 may include a solid structure. Accordingly, the above-described signal transmission and/or feeding between the radiators 112, 122 and 132 and the antenna driving IC chip may be performed with high efficiency.

The radiators 112, 122 and 132 and/or the transmission lines 114, 124 and 134 may include silver (Ag), gold (Au), copper (Cu), aluminum (Al), platinum (Pt), palladium (Pd), chromium (Cr), titanium (Ti), tungsten (W), niobium (Nb), tantalum (Ta), vanadium (V), iron (Fe), manganese (Mn), cobalt (Co), nickel (Ni), zinc (Zn), tin (Sn), molybdenum (Mo), calcium (Ca) or an alloy containing at least one of the metals. These may be used alone or in a combination of at least two therefrom.

In an embodiment, the radiators 112, 122 and 132 and/or the transmission lines 114, 124 and 134 may include silver (Ag) or a silver alloy (e.g., silver-palladium-copper (APC)), or copper (Cu) or a copper alloy (e.g., a copper-calcium (CuCa)) to implement a low resistance and a fine line width pattern.

In some embodiments, the radiators 112, 122 and 132 and/or the transmission lines 114, 124 and 134 may include a transparent conductive oxide such as indium tin oxide (ITO), indium zinc oxide (IZO), indium zinc tin oxide (ITZO), zinc oxide (ZnOx), etc.

In some embodiments, the radiators 112, 122 and 132 and/or the transmission lines 114, 124 and 134 may include a stacked structure of a transparent conductive oxide layer and a metal layer. For example, the antenna unit may include a double-layered structure of a transparent conductive oxide layer-metal layer, or a triple-layered structure of a transparent conductive oxide layer-metal layer-transparent conductive oxide layer. In this case, flexible property may be improved by the metal layer, and a signal transmission speed may also be improved by a low resistance of the metal layer. Corrosive resistance and transparency may be improved by the transparent conductive oxide layer.

The radiators 112, 122 and 132 and/or the transmission lines 114, 124 and 134 may include a blackened portion, so that a reflectance at a surface of radiators 112, 122 and 132 and/or the transmission lines 114, 124 and 134 may be decreased to suppress a visual pattern recognition due to a light reflectance.

In an embodiment, a surface of the metal layer included in the radiators 112, 122 and 132 and/or the transmission lines 114, 124 and 134 may be converted into a metal oxide or a metal sulfide to form a blackened layer. In an embodiment, a blackened layer such as a black material coating layer or a plating layer may be formed on the metal layer. The black material or plating layer may include silicon, carbon, copper, molybdenum, tin, chromium, molybdenum, nickel, cobalt, or an oxide, sulfide or alloy containing at least one therefrom.

A composition and a thickness of the blackened layer may be adjusted in consideration of a reflectance reduction effect and an antenna radiation property.

In some embodiments, the antenna structure 100 may further include signal pads 116, 126 and 136. For example, a first signal pad 116 may be connected to a terminal end portion of the first transmission line 114, a second signal pad 126 may be connected to a terminal end portion of the second transmission line 124, and a third signal pad 136 may be connected to a terminal end portion of the third transmission line 134.

In an embodiment, the first to third signal pads 116, 126 and 136 may be provided as substantially integral members with the first to third transmission lines 114, 124 and 134, respectively. For example, the terminal end portion of each of the first to third transmission lines 114, 124 and 134 may be provided as the first to third signal pads 116, 126 and 136, respectively.

In some embodiments, a ground pad (not illustrated) may be disposed around the signal pads 116, 126 and 136. For example, a pair of first ground pads may be disposed to face each other with the first signal pad 116 interposed therebetween. A pair of second ground pads may be disposed to face each other with the second signal pad 126 interposed therebetween. A pair of third ground pads may be disposed to face each other with the third signal pad 136 interposed therebetween.

The ground pad may be electrically and physically separated from the transmission lines 114, 124 and 134 and the signal pads 116, 126 and 136.

In some embodiments, the first signal pad 116, the second signal pad 126 and the third signal pad 136 may be arranged in a width direction of the dielectric layer 105, e.g., a third direction.

For example, the first signal pad 116, the second signal pad 126 and the third signal pad 136 may be spaced apart from each other along a third axis X3 extending in the third direction. The third axis X3 may be an imaginary straight line passing through centers of the first to third signal pads 116, 126 and 136 and extending in the third direction.

For example, the first direction may be inclined by a first tilting angle θ1 with respect to the third direction, and the second direction may be inclined by a second tilting angle θ2 with respect to the third direction.

In an embodiment, a circuit board included in the image display device may be bonded on end portions of the signal pads 116, 126 and 136 and the transmission lines 114, 124 and 134. In some embodiments, the ground pads may be arranged around the signal pads 116, 126 and 136, so that bonding stability of the circuit board may be further improved.

Referring to FIGS. 1 and 2, in some embodiments, the first direction may be inclined by the first tilting angle θ1 with respect to the width direction (e.g., the third direction) of the dielectric layer 105, and the second direction may be inclined by the second tilting angle θ2 with respect to the width direction of the dielectric layer 105. Accordingly, a deviation of a length difference between the first transmission line 114 and the second transmission line 124 and a length difference between the second transmission line 124 and the third transmission line 134 may be reduced.

In example embodiments, the first axis X1 and the second axis X2 may be inclined at a predetermined tilting angle with respect to the width direction of the dielectric layer 105. Accordingly, overall lengths of the transmission lines 114, 124, and 134 may be reduced, thereby preventing a signal loss and a resistance increase.

Additionally, the deviation of the length difference between the first transmission line 114 and the second transmission line 124 and the length difference between the second transmission line 124 and the third transmission line 134 may be reduced, so that accuracy of measuring the signal change based on the positional change along the first axis X1 or the second axis X2 may be improved.

In some embodiments, each of the first tilting angle θ1 and the second tilting angle θ2 may be in a range from 15° to 75°, preferably from 30° to 60°. Within the above range, the first radiator 112 and the third radiator 132 may be substantially symmetrically disposed at the same plane with respect to the second radiator 122. Accordingly, the signal change according to the positional change may be stably measured.

In an embodiment, the first tilting angle θ1 and the second tilting angle θ2 may be 45°.

As illustrated in FIG. 1, the first radiator 112 and the third radiator 132 may include a first impedance matching pattern 115 and a third impedance matching pattern 135, respectively.

For example, the first impedance matching pattern 115 may be directly connected to the first transmission line 114 and the third impedance matching pattern 135 may be directly connected to the third transmission line 134. Thus, a signal reception efficiency and an antenna gain of the first radiator 112 and the third radiator 132 may be improved.

In this case, the second radiator 122 may not include an impedance matching pattern. For example, the length of the second transmission line 124 may be greater than each length of the first transmission line 114 and the third transmission line 134. Accordingly, the first tilting angle θ1 and the second tilting angle θ2 may be formed within the above-described range.

For example, a signal and/or a power supplied to the second transmission line 124 longer than the first and third transmission lines 114 and 134 may be greater than that supplied to the first and third transmission lines 114 and 134. Accordingly, an impedance difference between the radiators 112, 122 and 132 may be alleviated, and driving reliability may be improved.

In some embodiments, when the second radiator 122 does not include an impedance matching pattern, a portion of the second transmission line 124 adjacent to the second signal pad 126 may have a solid structure. In an embodiment, a length of the solid portion of the second transmission line 124 may be substantially equal to a sum of the lengths of the first impedance matching pattern 115 and the first transmission line 114. In an embodiment, the length of the solid portion of the second transmission line 124 may be substantially equal to the sum of the lengths of the third impedance matching pattern 135 and the third transmission line 134.

As illustrated in FIG. 2, the second radiator 122 may include a second impedance matching pattern 125. For example, the second impedance matching pattern 125 may be directly connected to the second transmission line 124. Accordingly, a signal reception efficiency and an antenna gain of the second radiator 122 may be improved.

In this case, the first radiator 112 and the third radiator 132 may not include an impedance matching pattern. For example, the length of the second transmission line 124 may be smaller than each length of the first transmission line 114 and the third transmission line 134. Accordingly, the first tilting angle θ1 and the second tilting angle θ2 may be formed within the above-described range.

For example, the signal and/or the power supplied to the second transmission line 124 shorter than the first and third transmission lines 114 and 134 may be less than that supplied to each of the first and third transmission lines 114 and 134. Accordingly, the impedance difference between the radiators 112, 122 and 132 may be alleviated, and driving reliability may be improved.

In some embodiments, when the first and third radiators 112 and 132 do not include the impedance matching pattern, portions of the first and third transmission lines 114 and 134 each adjacent to the first and third signal pads 116 and 136 may be formed as a solid structure. In an embodiment, each length of the solid portions of the first and third transmission lines 114 and 134 may be substantially equal to a sum of the lengths of the second impedance matching pattern 125 and the second transmission line 124.

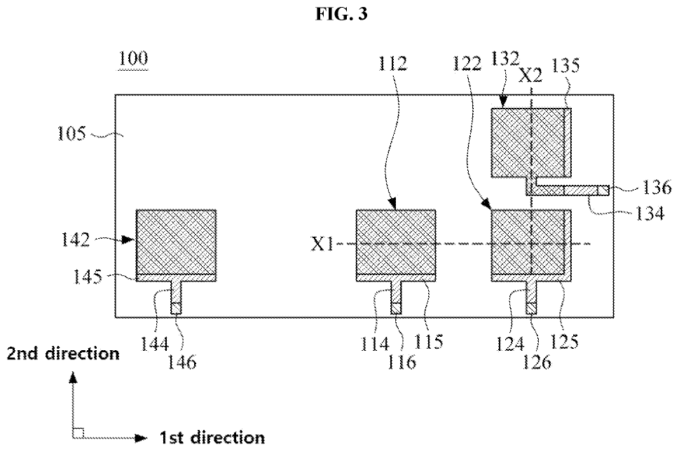

FIG. 3 is a schematic plan view illustrating an antenna structure in accordance with exemplary embodiments.

Referring to FIG. 3, the first direction may be parallel to the width direction of the dielectric layer 105, and the second direction may be perpendicular to the width direction of the dielectric layer 105.

The first radiator 112, the second radiator 122 and the third radiator 132 may include the first impedance matching pattern 115, the second impedance matching pattern 125 and the third impedance matching pattern 135.

As illustrated in FIG. 3, the first radiator 112, the second radiator 122 and the third radiator 132 may be efficiently disposed in a relatively narrow space. Accordingly, the antenna structure may be applied to a mobile device and/or a display device having a narrow bezel area with enhanced spatial efficiency.

The first impedance matching pattern 115 and the second impedance matching pattern 125 may be directly connected to the first transmission line 114 and the second transmission line 124, respectively. The second impedance matching pattern 125 may be disposed to surround two sides among four sides of the second radiator 122. Accordingly, the signal efficiency and the antenna gain of the second radiator 122 may be additionally improved.

The third impedance matching pattern 135 may be physically separated from the third transmission line 134. For example, the third impedance matching pattern 135 may be formed at one side of the third radiator 132, and the third transmission line 134 may be connected to another side of the third radiator 132. In this case, a portion of the third transmission line 134 adjacent to the third signal pad 136 may have a solid structure.

In some embodiments, the antenna structure 100 may further include a fourth radiator 142 spaced apart from the first radiator 112, the second radiator 122 and the third radiator 132. The antenna structure 100 may further include a fourth transmission line 144 connected to the fourth radiator 142 at the same layer as that of the fourth radiator 142.

For example, the fourth radiator 142 may include a fourth impedance matching pattern 145 directly connected to the fourth transmission line 144. Accordingly, the signal efficiency and antenna gain of the fourth radiator 142 may be improved.

For example, the fourth radiator 142 may serve as a transmission radiator for a motion sensing and may emit an electromagnetic wave toward a sensing object. For example, the fourth radiator 142 may serve as a transmission radiator of the antenna structure 100.

For example, the first radiator 112, the second radiator 122 and the third radiator 132 may serve as reception radiators and may receive signals reflected from the sensing target. For example, the first radiator 112, the second radiator 122 and the third radiator 132 may serve as reception radiators of the antenna structure 100.

Accordingly, the antenna structure 100 may receive and/or transmit electromagnetic wave signals for the sensing object, and the motion sensor may recognize decrease/increase of the signals according to a positional change and a distance of the sensing object.

In some embodiments, the antenna structure 100 may further include a fourth signal pad 146 electrically connected to one end portion of the fourth transmission line 144. In an embodiment, the fourth signal pad 146 may be formed as a substantially integral member with the fourth transmission line 144. For example, a terminal end portion of the fourth transmission line 144 may serve as the fourth signal pad 146.

In an embodiment, the antenna structure 100 may include a pair of fourth ground pads (not illustrated) facing each other with the fourth signal pad 146 interposed therebetween.

The above-described impedance matching patterns 115, 125, 135 and 145, portion having the solid structure of the transmission lines 114, 124, 134 and 144, and the signal pads 116, 126, 136 and 146 may be disposed in a non-display area of the display device. Accordingly, the antenna structure 100 may be prevented from being visually recognized by a user while providing improved antenna performance.

The radiators 112, 122, 132 and 142 may have a polygonal shape such as a triangle, a quadrangle, a rhombus, a pentagon, a hexagon, etc., or may have a circular shape.

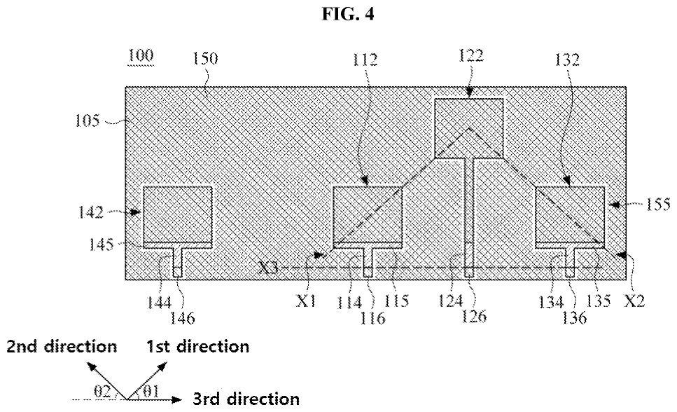

FIG. 4 is a schematic plan view illustrating an antenna structure in accordance with exemplary embodiments.

Referring to FIG. 4, the antenna structure 100 may further include a dummy mesh pattern 150 disposed around the radiators 112, 122, 132 and 142. For example, the dummy mesh pattern 150 may be electrically and physically separated from the radiators 112, 122, 132 and 142 and the transmission lines 114, 124, 134 and 144 by a separation region 155.

For example, a conductive layer containing the metal or the alloy as described above may be formed on the dielectric layer 105. A mesh structure may be formed while etching the conductive layer along profiles of the radiators 112, 122, 132 and 142 and the transmission lines 114, 124, 134 and 144 as described above. Accordingly, the dummy mesh pattern 150 spaced apart from the radiators 112, 122, 132 and 142 and the transmission lines 114, 124, 134 and 144 may be formed by the separation region 155.

Thus, transmittance of the antenna structure 100 may be improved. The dummy mesh pattern may be distributed, so that optical properties around the radiators 112, 122, 132 and 142 may become uniform. Therefore, the antenna structure 100 may be prevented from being visually recognized by the user.

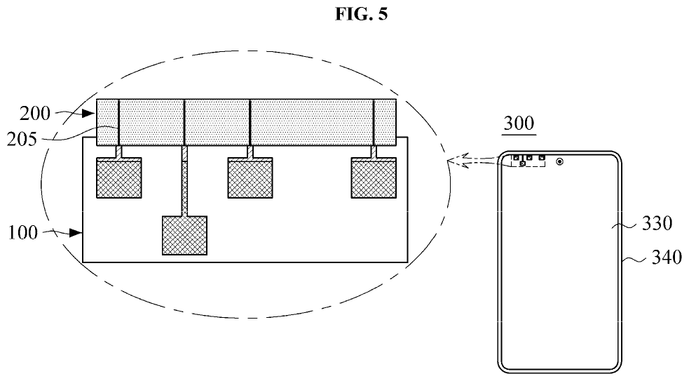

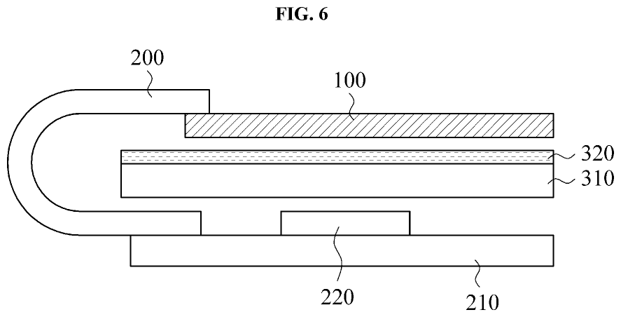

FIGS. 5 and 6 are a schematic plan view and a cross-sectional view illustrating a display device in accordance with exemplary embodiments.

FIG. 5 illustrates a front portion or a window surface of an image display device 300. The front portion of the image display device 300 may include a display area 330 and a non-display area 340. The non-display area 340 may correspond to, e.g., a light-shielding portion or a bezel portion of the image display device 300.

The antenna structure 100 may be disposed toward the front portion of the image display device 300, and may be disposed on, e.g., a display panel.

In an embodiment, the antenna structure 100 may be formed throughout the display area 330 and the non-display area 340 of the image display device 300. In one embodiment, the radiators 112, 122, 132 and 142 may at least partially overlie the display area 330.

As described above, the impedance matching patterns 115, 125, 135 and 145, portions having a solid structure of the transmission lines 114, 124, 134 and 144, and the signal pads 116, 126, 136 and 146 may overlap the non-display area 340.

In some embodiments, the antenna structure 100 may be located in a central portion of one side of the image display device 300. Accordingly, deterioration of sensing performance at any region of the display device may be prevented, and detection of motions, gestures or distances in all directions may be implemented on the front portion of the display device 300.

In some embodiments, one end of the transmission line 114, 124, 134 and 144 may be connected to the radiator 112, 122 and 132, respectively, and the other end of the transmission line 114, 124, 134 and 144 may be bonded to a circuit board 200.

The circuit board 200 may include, e.g., a flexible printed circuit board (FPCB). For example, a conductive bonding structure such as an anisotropic conductive film (ACF) may be attached to the other ends of the transmission lines 114, 124, 134 and 144. The circuit board may be placed on the conductive bonding structure, and then heated and pressed.

The circuit board 200 may include a circuit wiring 205 bonded to the other end of the transmission line. The circuit wiring 205 may serve as an antenna feed wiring. For example, one end of the circuit wiring 205 may be exposed to an outside, and the exposed one end of the circuit wiring 205 may be bonded to the transmission lines 114, 124, 134 and 144. Thus, the circuit wiring 205 and the antenna structure 100 may be electrically connected.

An antenna driving IC chip may be mounted on the circuit board 200. In an embodiment, an intermediate circuit board such as a rigid printed circuit board may be disposed between the circuit board 200 and the antenna driving IC chip. In an embodiment, the antenna driving IC chip may be directly mounted on the circuit board 200.

A motion sensor driving circuit may be mounted on the circuit board 200. For example, the antenna structure 100 and the circuit board 200 may be electrically connected, so that signal information created from the antenna structure 100 may be transferred to the motion sensor driving circuit. Accordingly, a motion recognition sensor including the antenna structure 100 may be provided.

Referring to FIG. 6, the display device 300 may include a display panel 310 and the above-described antenna structure 100 disposed on the display panel 310.

In example embodiments, an optical layer 320 may be further included on the display panel 310. For example, the optical layer 320 may be a polarization layer including a polarizer or a polarizing plate.

In an embodiment, a cover window may be disposed on the antenna structure 100. The cover window may include, e.g., glass (e.g., ultra-thin glass (UTG)) or a transparent resin film. Accordingly, an external impact applied to the antenna structure 100 may be reduced or absorbed.

For example, the antenna structure 100 may be disposed between the optical layer 320 and the cover window. In this case, the dielectric layer 105 and the optical layer 320 disposed under the radiators 112, 122, 132 and 142 may commonly function as a dielectric layer of the radiators 112, 122, 132 and 142. Accordingly, an appropriate permittivity may be achieved so that the motion sensing performance of the antenna structure 100 may be sufficiently implemented.

For example, the optical layer 320 and the antenna structure 100 may be laminated through a first adhesive layer, and the antenna structure 100 and the cover window may be laminated through a second adhesive layer.

A flexible printed circuit board 200 may be bent along, e.g., a lateral side curved profile of the display panel 310 to be disposed at a rear portion of the image display device 300 and extend toward an intermediate circuit board 210 (e.g., the main board) on which the driving IC chip is mounted.

The flexible printed circuit board 200 and the intermediate circuit board 210 may be bonded or connected to each other through a connector, so that feeding and antenna driving control to the antenna structure 100 by the antenna driving IC chip may be implemented.

In some embodiments, a motion sensor driving circuit 220 may be mounted on the intermediate circuit board 210. In an embodiment, the motion sensor driving circuit 220 may include a proximity sensor, a gesture sensor, an acceleration sensor, a gyroscope sensor, a position sensor, a geomagnetic sensor, etc.

In some embodiments, the first radiators 112, 122, 132 and 142 may be coupled to the motion sensor driving circuit 220.

In an embodiment, the antenna structure 100 may be bonded to the intermediate circuit board 210 or electrically connected to the motion sensor driving circuit 220 through the circuit board 200. Accordingly, the change of signal strength of the antenna structure 100 along the first and second axes X1 and X1 may be transmitted to the motion sensor driving circuit 220.

In some embodiments, signal intensities of the first radiator 112, the second radiator 122 and the third radiator 132 according to the movement of the sensing target from a specific first location to a specific second location may be measured to measure the motion of the sensing target.

For example, the motion sensor driving circuit 220 coupled with the antenna structure 100 may measure the changes of the signal intensity between the second radiator 122 and the first radiator 112, and between the second radiator 122 and the third radiator 132 corresponding to the movement from the first location to the second location to detect the motion.

For example, the movement of the sensing target in the first direction may be sensed by the second radiator 122 and the first radiator 112. The movement of the sensing target in the second direction may be sensed by the second radiator 122 and the third radiator 132.

Thus, the change in signal strength according to motion/position in two axes perpendicular to each other may be provided from the antenna structure 100 to the motion sensor driving circuit 220, and the movement, motion and distance of each axis may be measured in the motion sensor driving circuit 220.

In an embodiment, the motion sensor driving circuit 220 may include a motion detection circuit. Signal information transmitted from the antenna structure 100 may be converted/calculated into location information or distance information through the motion detection circuit.

In an embodiment, the antenna structure 100 may be electrically connected to a radar sensor circuit, and thus signal transmission/reception information may be transmitted to a radar processor. For example, the antenna structure 100 may be connected to the radar processor through the circuit board 200 and the intermediate circuit board 210. Accordingly, a radar sensor including the antenna structure may be provided.

The radar sensor may analyze transmission/reception signals to detect information about the sensing target. For example, the antenna structure 100 may transmit the transmission signal and receive the reception signal reflected by the sensing target to measure the distance to the sensing target.

For example, the distance of the sensing target may be calculated by measuring a time required for the signal transmitted from the antenna structure to be reflected by the sensing target and received again by the antenna structure.

What is claimed is:

1. An antenna structure comprising:
a first radiator;
a second radiator arranged along a first direction together with the first radiator; and
a third radiator arranged along a second direction perpendicular to the first direction together with the second radiator,
wherein at least one of the first radiator, the second radiator and the third radiator comprises an impedance matching pattern having a solid structure.

2. The antenna structure according to claim 1, further comprising:
a first transmission line connected to the first radiator at the same layer as that of the first radiator;
a second transmission line connected to the second radiator at the same layer as that of the second radiator; and
a third transmission line connected to the third radiator at the same layer as that of the third radiator.

3. The antenna structure according to claim 2, wherein at least one of the first transmission line, the second transmission line and the third transmission line has a solid structure.

4. The antenna structure according to claim 2, further comprising a dielectric layer on which the first radiator, the second radiator and the third radiator are disposed,
wherein the first direction is inclined by a first tilting angle with respect to a width direction of the dielectric layer, and the second direction is inclined by a second tilting angle with respect to the width direction of the dielectric layer.

5. The antenna structure according to claim 4, wherein each of the first tilting angle and the second tilting angle is in a range from 30° to 60°.

6. The antenna structure according to claim 4, wherein the impedance matching pattern comprises a first impedance matching pattern included in the first radiator and directly connected to the first transmission line, and a third impedance matching pattern included in the third radiator and directly connected to the third transmission line.

7. The antenna structure according to claim 4, wherein the impedance matching pattern comprises a second impedance matching pattern included in the second radiator and directly connected to the second transmission line.

8. The antenna structure according to claim 2, further comprising a dielectric layer on which the first radiator, the second radiator, and the third radiator are disposed,
wherein the first direction is parallel to a width direction of the dielectric layer, the second direction is perpendicular to the width direction of the dielectric layer.

9. The antenna structure according to claim 8, wherein the impedance matching pattern comprises a first impedance matching pattern included in the first radiator, a second impedance matching pattern included in the second radiator, and a third impedance matching pattern included in the third radiator, and
the first impedance matching pattern and the second impedance matching pattern are directly connected to the first transmission line and the second transmission line, respectively.

10. The antenna structure according to claim 9, wherein the third impedance matching pattern is physically spaced apart from the third transmission line.

11. The antenna structure according to claim 9, wherein the second impedance matching pattern surrounds two sides among four sides of the second radiator.

12. The antenna structure according to claim 1, wherein the first radiator, the second radiator and the third radiator are disposed at the same layer.

13. The antenna structure according to claim 1, further comprising:
a fourth radiator spaced apart from the first radiator, the second radiator and the third radiator; and
a fourth transmission line connected to the fourth radiator at the same layer as that of the fourth radiator,
wherein the impedance matching pattern comprises a fourth impedance matching pattern included in the fourth radiator and directly connected to the fourth transmission line.

14. The antenna structure according to claim 13, wherein the first radiator, the second radiator and the third radiator serve as a receiving radiation unit, and the fourth radiator serves as a transmitting radiation unit.

15. A motion recognition sensor comprising the antenna structure according to claim 1.

16. An image display device comprising:
a display panel; and
the antenna structure according to claim 1 disposed on the display panel.

17. The image display device according to claim 16, wherein the first direction is inclined by a first tilting angle with respect to a length direction or a width direction of the display panel, and
the second direction is inclined by a second tilting angle with respect to the length direction or the width direction of the display panel.

18. The image display device according to claim 16, further comprising:
a motion sensor driving circuit coupled to the antenna structure; and
a flexible circuit board (FPCB) electrically connecting the antenna structure and the motion sensor driving circuit.
